(19) United States
(12) Patent Application Publication
(10) Pub. No.: US 2026/0123425 A1
(43) Pub. Date: Apr. 30, 2026

(54) CAMM MODULE RETENTION FOR COMPRESSIVE MOUNT CONNECTOR AND HEATSINK

(71) Applicant: Intel Corporation, Santa Clara, CA (US)

(72) Inventors: Phil GENG, Washougal, WA (US); Xiang LI, Portland, OR (US); George VERGIS, Portland, OR (US); Jeffory SMALLEY, East Olympia, WA (US)

(21) Appl. No.: 19/432,151

(22) Filed: Dec. 24, 2025

Related U.S. Application Data
(60) Provisional application No. 63/842,093, filed on Jul. 11, 2025.

(51) Int. Cl. H10W 40/60; H10B 80/00; H10W 40/00; H10W 40/20; H10W 40/22; H10W 70/60; H10W 72/30; H10W 90/00; H10W 90/10

(52) U.S. Cl. CPC H10W 40/611; H10B 80/00; H10W 40/037; H10W 40/228; H10W 40/235; H10W 40/242; H10W 70/611; H10W 72/365; H10W 90/10; H10W 90/736

(57) ABSTRACT

An apparatus, comprising an interposer; a memory module, comprising a plurality of memory chips, and mounted to the interposer; and a heatsink, fastened to the interposer and configured to compress the interposer against the memory module.

### CROSS-REFERENCE TO RELATED APPLICATIONS

This application claims priority to U.S. provisional application 63/842,093, filed on Jul. 11, 2025, the entire contents of which are incorporated herein by reference.

### BACKGROUND

Memory chips may be attached to a heat sink during manufacture, such as for thermal protection of the memory chips. In one manufacturing technique, memory chips may be mounted to a substrate or printed circuit board (PCB), and the resulting unit may be attached to a heatsink. When a compressively mounted connector is used to mount the memories chip on the PCB, this combination of memory chips and substrate or PCB may be understood as a compressive attached memory module (CAMM). The CAMM may require both the use of a compressive mount technology (CMT) and a thermal mount during the manufacturing process.

### BRIEF DESCRIPTION OF THE DRAWINGS

In the drawings, like reference characters generally refer to the same parts throughout the different views. The drawings are not necessarily to scale, emphasis instead generally being placed upon illustrating the exemplary principles of the disclosure. In the following description, various exemplary embodiments of the disclosure are described with reference to the following drawings, in which:

FIG. 1 depicts an exemplary CAMM layout;

FIG. 2 depicts a conventional structure for connecting the module to the heatsink;

FIG. 3 depicts a heatsink retention for a CAMM with a CMT connector;

FIG. 4 depicts the configuration of FIG. 3 with a screw and a nut;

FIG. 5 depicts the configuration of FIG. 4 with a spring between the nut and the heatsink and retention element; and

FIG. 6 depicts the device of FIG. 5 with an optional back plate.

### DESCRIPTION

The following detailed description refers to the accompanying drawings that show, by way of illustration, exemplary details and embodiments in which aspects of the present disclosure may be practiced.

The word “exemplary” is used herein to mean “serving as an example, instance, or illustration”. Any embodiment or design described herein as “exemplary” is not necessarily to be construed as preferred or advantageous over other embodiments or designs.

Throughout the drawings, it should be noted that like reference numbers are used to depict the same or similar elements, features, and structures, unless otherwise noted.

The phrase “at least one” and “one or more” may be understood to include a numerical quantity greater than or equal to one (e.g., one, two, three, four, [ . . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of individual listed elements.

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. For instance, the phrase “a plurality” may be understood to include a numerical quantity greater than or equal to two (e.g., two, three, four, five, [ . . . ], etc.).

The phrases “group (of)”, “set (of)”, “collection (of)”, “series (of)”, “sequence (of)”, “grouping (of)”, etc., in the description and in the claims, if any, refer to a quantity equal to or greater than one, i.e., one or more. The terms “proper subset”, “reduced subset”, and “lesser subset” refer to a subset of a set that is not equal to the set, illustratively, referring to a subset of a set that contains less elements than the set.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and represent any information as understood in the art.

The terms “processor” or “controller” as, for example, used herein may be understood as any kind of technological entity that allows handling of data. The data may be handled according to one or more specific functions executed by the processor or controller. Further, a processor or controller as used herein may be understood as any kind of circuit, e.g., any kind of analog or digital circuit. A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, controller, or logic circuit. It is understood that any two (or more) of the processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

As used herein, “memory” is understood as a computer-readable medium (e.g., a non-transitory computer-readable medium) in which data or information can be stored for retrieval. References to “memory” included herein may thus be understood as referring to volatile or non-volatile memory, including random access memory (RAM), read-only memory (ROM), flash memory, solid-state storage, magnetic tape, hard disk drive, optical drive, 3D XPoint™, among others, or any combination thereof. Registers, shift registers, processor registers, data buffers, among others, are also embraced herein by the term memory. The term “software” refers to any type of executable instruction, including firmware.

“Heatsink fins” as used herein may refer to protruding structures formed on a heatsink that are configured to increase the effective surface area of the heatsink. The heatsink fins facilitate the transfer of thermal energy from the heatsink to the surrounding environment, for example by convective and/or radiative heat transfer. Heatsink fins may have any suitable geometry, including plate-like, pin-like, or ribbed configurations, and may be arranged in any suitable pattern or orientation. Unless explicitly stated otherwise, the term “heatsink fins” encompasses monolithic structures formed integrally with the heatsink as well as fins attached to the heatsink as separate components. That is, where the term “monolithic” is used, this should be understood as referring to an object that is formed as and from a single piece (e.g., such as by machining or casting).

In the following, a generic component level loading mechanism for an individual CAMM module with a CMT connector and heatsink is disclosed.

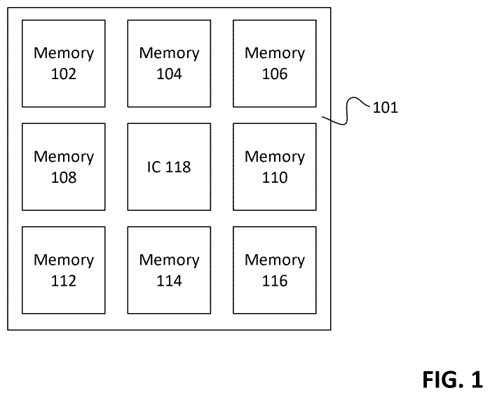

FIG. 1 depicts an exemplary CAMM layout. In this figure, a PCB 101 includes a plurality of memory chips (a single memory chip is conceivable, although a plurality of memory chips is more common, and the remainder of the disclosure will refer to a plurality for convenience), which are depicted herein in an exemplary configuration as memory chips 102, 104, 106, 108, 110, 112, 114, and 116. The CAMM may be attached to a heatsink. This attachment to the heatsink may include at least one additional module to generate a compression-attachment between the CAMM and the heatsink, as well as a thermal connection (e.g., such as with a heat-transferring layer between the memory chips and the heatsink).

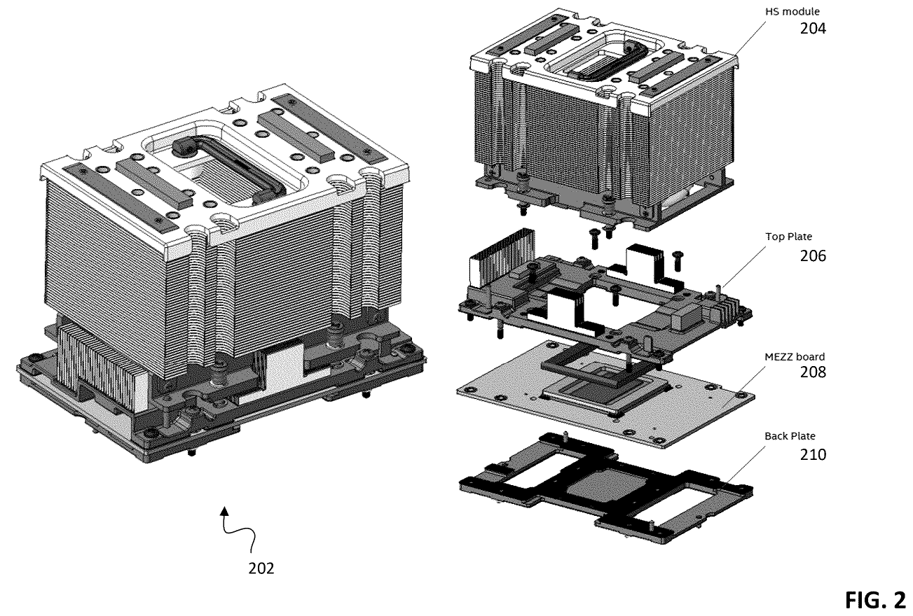

FIG. 2 depicts a conventional structure for connecting the CAMM to the heatsink. In this figure, a package that includes the CAMM, the heatsink, and elements for connection of the CAMM and the heatsink, is depicted as 202. Specifically, this package includes the heatsink module 204, which is configured to divert thermal energy from the one or more memory chips to a surrounding environment, such as by radiating the thermal energy to a surrounding area via a plurality of heatsink fins. It includes a top plate 206, which is configured to create a mechanical attachment to the heatsink 204 and to a memory module 208, which may be similar or identical to the module of FIG. 1. The memory module 208 may be connected to a back plate 210, such as for stability purposes. In this configuration, the memory module 208 is not directly affixed to the heatsink, but rather, there is a mechanical connection between the heatsink 204 and the top plate 206, and there is another mechanical connection between the top plate 206 and the back plate 210, which, together, generate a compressive force that causes the heatsink 204 and the memory module 208 to make contact with one another. It is emphasized, however, that, in this configuration, no singular fixation device (e.g. a screw, a rivet, etc.,) runs through both the heatsink 204 and the memory module 208. Otherwise stated, conventional thermal mechanical solutions are mostly integrated retention designs on an “OAM-like interposer” (e.g., similar to Open Accelerator Module (OAM) retention schemes). There is no general thermal mechanical solution for an individual CAMM that places the CMT and heatsink at the memory component level.

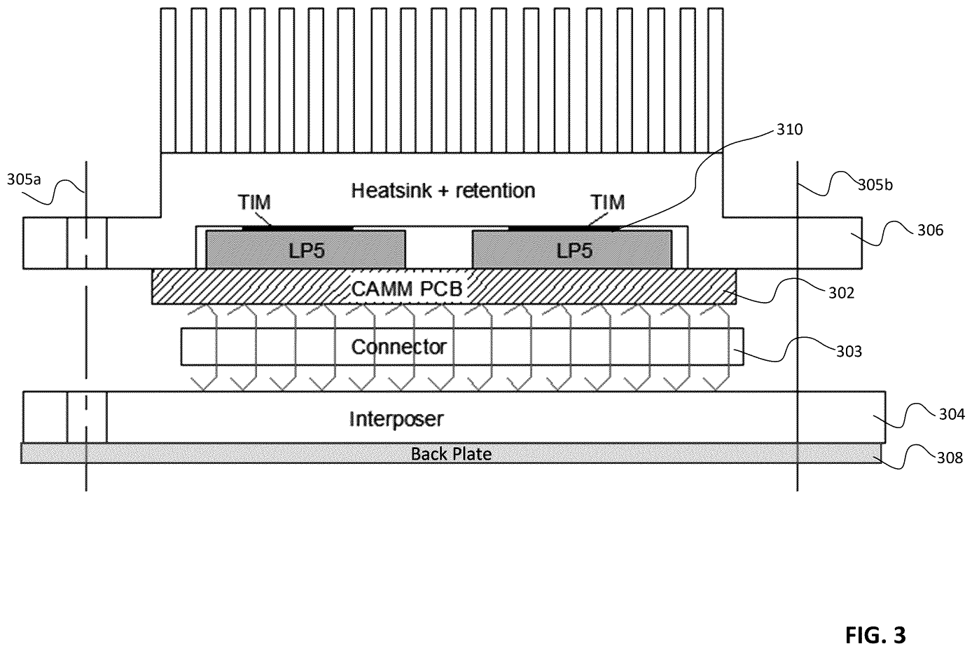

In the following, a device and method for attaching the CAMM and the CMT connector directly to the interposer board through the heatsink is described. FIG. 3 depicts a heatsink retention for a CAMM with a CMT connector. In this figure, a CAMM 302 is electrically connected to an interposer 304 via a connector 303. The skilled person will appreciate the interworkings of electrical connector 303, the details of which are outside the scope of this application. A monolithic heatsink and retention element 306 is fastened to the interposer 304 via fasteners 305a and 305b through mounting holes in the heatsink and retention element 306 and the interposer 304. These mounting holes may be configured to line up with one another such that a plurality of fasteners may each be placed through a hole in the heatsink and retention element 306 and through a hole in the interposer 304. This connection of the heatsink and retention element 306 to the interposer 304 via fasteners 305a and 305b places a compressive force between the heatsink and retention element 306 and the interposer 304, which compresses each of these against the CAMM 302. In this manner, a compressive force is applied by the CAMM 302 and the interposer against the connector 303, and a compressive force is applied by the heatsink and retention element 306 and the interposer 304/connector 303 against the CAMM 302. In some configurations, an optional back plate 308 may be used for high CMT or thermal load requirements. Where the back plate 308 is present, the fasteners may run from the heatsink and retention element 306, through the interposer 304, and to/through the back plate 308.

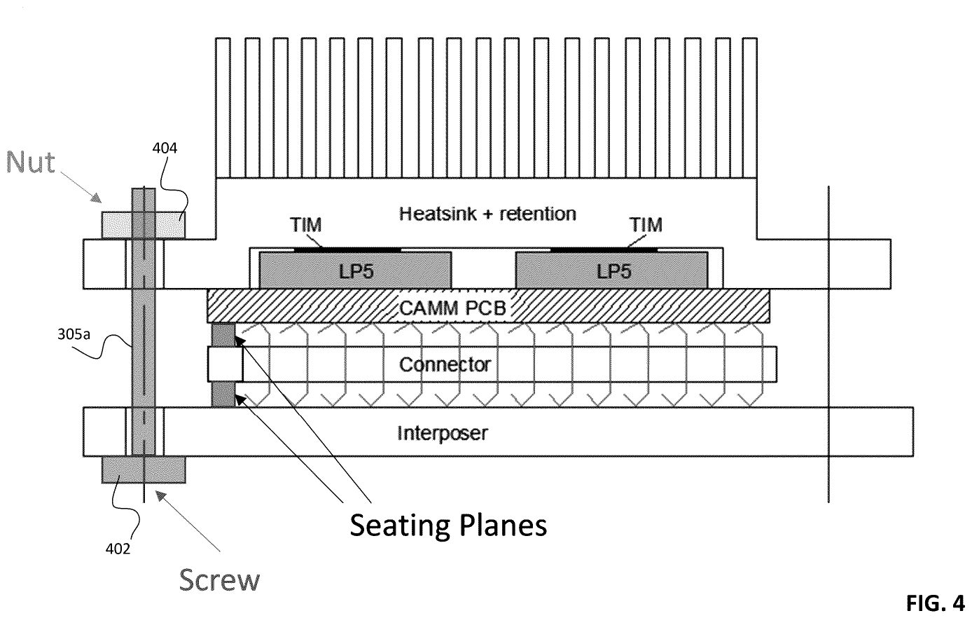

FIG. 4 depicts the configuration of FIG. 3, but with the addition of a screw 402 and a nut 404. In this manner, mechanical force is introduced via the screw and nut to generate compression between the heatsink and retention element and the interposer. This may be achieved by placing a screw 402 within the mounting holes of the heatsink and retention element and the interposer and by tightening the nut 404 to produce the desired force. The amount of desired force may depend on the implementation and is achieved by the degree of tightening of the screw relative to the nut. The seating planes of the heatsink and retention element and the interposer may ensure adequate contact of the connector pins to the CAMM and to the interposer.

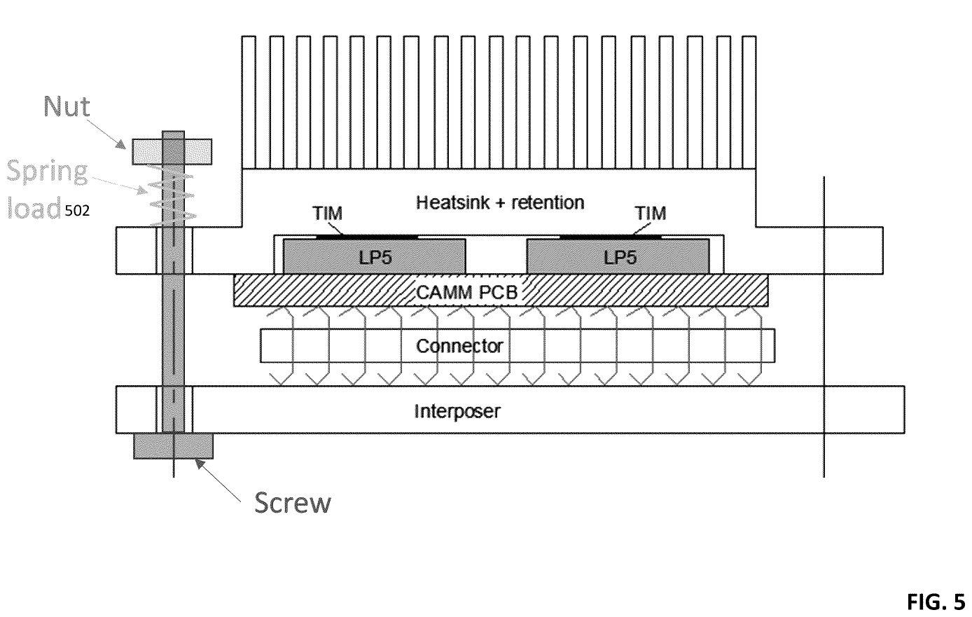

FIG. 5 depicts the configuration of FIG. 4, but with the addition of a spring 502 between the nut and the heatsink and retention element. By adding spring 502, the compressive forces are not dictated exclusively by the tension of the nut and screw against the heatsink and retention device and the interposer, but instead primarily by the spring constant of spring 502 and the magnitude of spring displacement caused by the tightening of the nut. This may offer an improved manner of controlling the compressive forces as compared to configurations in which no spring is used.

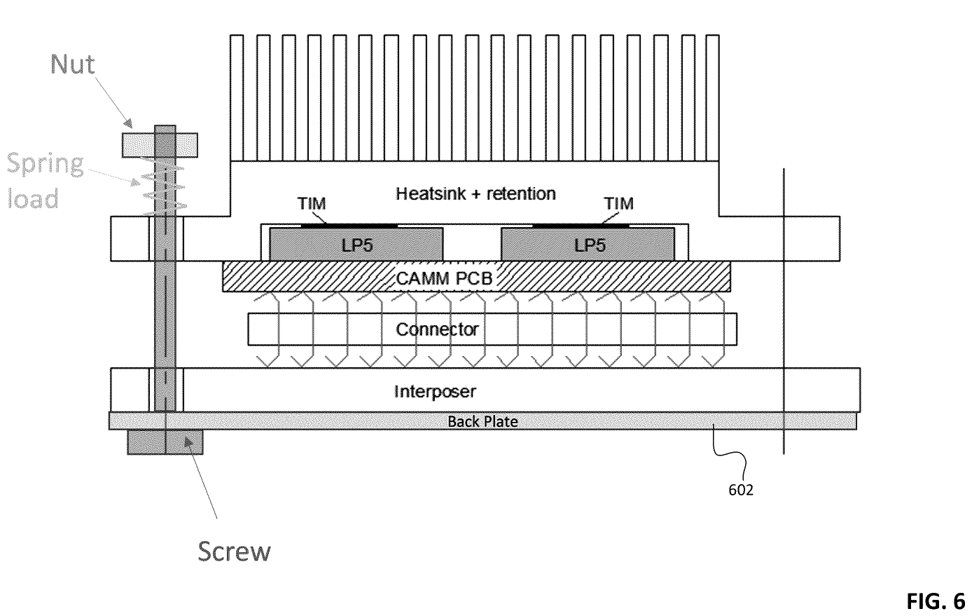

FIG. 6 depicts the device of FIG. 5, but with the addition of optional back plate 602, which may stiffen and reinforce the device, which may be desirable in certain configurations. Of note, although the back plate 602 is shown in combination with spring 502, it may be implemented in configurations with or without spring 502, as desired.

The skilled person will appreciate that the CAMM may be implemented in any of a variety of sizes, as its desirable size will depend on a quantity, size, and arrangement of memory chips used in the CAMM. In sample configuration that is set forth herein for demonstrative purposes only, the CAMM may be 47 mm by 51.6 mm. In this manner, each memory chip may be approximately 15×16 mm. The configuration of memory chips may include mounting areas on opposite sides. The mounting areas may be, for example, 3 mm. Again, these dimensions are provided only for demonstrative purposes and are not intended to be limiting.

Additional aspects of the invention will be disclosed by way of Example.

In Example 1, an apparatus, comprising an interposer; a memory module, comprising a plurality of memory chips, and mounted to the interposer; and a heatsink, fastened to the interposer and configured or positioned to compress the interposer against the memory module.

In Example 2, the apparatus of Example 1, wherein the heatsink comprises a heatsink portion and a fastening portion; and wherein the fastening portion comprises a plurality of first holes for fastening.

In Example 3, the apparatus of Example 2, wherein the heatsink monolithically comprises the heatsink portion and the fastening portion.

In Example 4, the apparatus of Example 2 or 3, wherein the interposer comprises a plurality of second holes that align with the plurality of first holes; further comprising a plurality of fasteners; and wherein each fastener of the plurality of fasteners extends transversely through a first hole of the plurality of first holes and a second hole of the plurality of second holes.

In Example 5, the apparatus of any one of Examples 1 to 4, wherein the plurality of fasteners are screws.

In Example 6, the apparatus of any one of Examples 1 to 5, further comprising a plurality of springs, each spring of the plurality of springs positioned around a fastener of the plurality of fasteners; and wherein the plurality of springs are configured to exert a force against the heatsink toward the interposer, or against the interposer toward the heatsink.

In Example 7, the apparatus of any one of Examples 1 to 6, further comprising a thermal interface material, connecting a memory chip of the plurality of memory chips to the heatsink.

In Example 8, the apparatus of any one of Examples 1 to 7, wherein the plurality of memory chips comprises a plurality of dual in-line memories (DIMMs).

In Example 9, a heatsink, comprising: a first side; a second side, opposite the first side; a plurality of heatsink fins, extending from the first side, and configured to radiate heat; a first fastening portion comprising a first hole; and a second fastening portion comprising a second hole; wherein the first fastening portion and the second fastening portion are configured to cause the heatsink to exert a force against a memory module; and wherein the second side comprises a recess between the first fastening portion and the second fastening portion, and wherein the recess is configured to accommodate one or more memory chips.

In Example 10, the heatsink of Example 9, wherein the heatsink is monolithic.

In Example 11, an apparatus, comprising: an interposer; a memory module, comprising a plurality of memory chips, and mounted to the interposer; and a heatsink, for compressing the interposer against the memory module.

In Example 12, the apparatus of Example 11, wherein the heatsink comprises a heatsink portion and a fastening portion; and wherein the fastening portion comprises a plurality of first holes for fastening.

In Example 13, the apparatus of Example 12, wherein the heatsink monolithically comprises the heatsink portion and the fastening portion.

In Example 14, the apparatus of Example 12 or 13, wherein the interposer comprises a plurality of second holes that align with the plurality of first holes; further comprising a plurality of fasteners; and wherein each fastener of the plurality of fasteners extends transversely through a first hole of the plurality of first holes and a second hole of the plurality of second holes.

In Example 15, the apparatus of any one of Examples 11 to 14, wherein the plurality of fasteners are screws.

In Example 16, the apparatus of any one of Examples 11 to 15, further comprising a plurality of springs, each spring of the plurality of springs positioned around a fastener of the plurality of fasteners; and wherein the plurality of springs are for exerting a force against the heatsink toward the interposer, or against the interposer toward the heatsink.

In Example 17, the apparatus of any one of Examples 11 to 16, further comprising a thermal interface material, connecting a memory chip of the plurality of memory chips to the heatsink.

In Example 18, the apparatus of any one of Examples 11 to 17, wherein the plurality of memory chips comprises a plurality of dual in-line memories (DIMMs).

In Example 19, a heatsink, comprising: a first side; a second side, opposite the first side; a plurality of heatsink fins, extending from the first side, for radiating heat; a first fastening portion comprising a first hole; and a second fastening portion comprising a second hole; wherein the first fastening portion and the second fastening portion are for causing the heatsink to exert a force against a memory module; and wherein the second side comprises a recess between the first fastening portion and the second fastening portion, and wherein the recess is for accommodating one or more memory chips.

In Example 20, the heatsink of Example 19, wherein the heatsink is monolithic.

In Example 21, a method of assembling a memory module, comprising: attaching a memory module comprising a plurality of memory chips to an interposer; and attaching a heatsink to the interposer, wherein the attaching the heatsink to the interposer causes the interposer to exert a force against the memory module.

In Example 22, the method of Example 21, wherein the attaching the heatsink to the interposer comprises attaching the heatsink to the interposer with a common fastener.

In Example 23, the apparatus of any one of Examples 1 to 8, wherein the apparatus is configured as a personal computer, a laptop computer, a tablet computer, a smartphone, or a wearable device.

While the above descriptions and connected figures may depict components as separate elements, skilled persons will appreciate the various possibilities to combine or integrate discrete elements into a single element. Such may include combining two or more circuits for form a single circuit, mounting two or more circuits onto a common chip or chassis to form an integrated element, executing discrete software components on a common processor core, etc. Conversely, skilled persons will recognize the possibility to separate a single element into two or more discrete elements, such as splitting a single circuit into two or more separate circuits, separating a chip or chassis into discrete elements originally provided thereon, separating a software component into two or more sections and executing each on a separate processor core, etc.

It is appreciated that implementations of methods detailed herein are demonstrative in nature, and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method.

All acronyms defined in the above description additionally hold in all claims included herein.

What is claimed is:

1. An apparatus, comprising:
an interposer;
a memory module, comprising a plurality of memory chips, and mounted to the interposer; and
a heatsink, fastened to the interposer and positioned to compress the interposer against the memory module.

2. The apparatus of claim 1, wherein the heatsink comprises a heatsink portion and a fastening portion; and wherein the fastening portion comprises a plurality of first holes for fastening.

3. The apparatus of claim 2, wherein the heatsink monolithically comprises the heatsink portion and the fastening portion.

4. The apparatus of claim 2, wherein the interposer comprises a plurality of second holes that align with the plurality of first holes; further comprising a plurality of fasteners; and wherein each fastener of the plurality of fasteners extends transversely through a first hole of the plurality of first holes and a second hole of the plurality of second holes.

5. The apparatus of claim 1, wherein the plurality of fasteners are screws.

6. The apparatus of claim 1, further comprising a plurality of springs, each spring of the plurality of springs positioned around a fastener of the plurality of fasteners; and wherein the plurality of springs are configured to exert a force against the heatsink toward the interposer, or against the interposer toward the heatsink.

7. The apparatus of claim 1, further comprising a thermal interface material, connecting a memory chip of the plurality of memory chips to the heatsink.

8. The apparatus of claim 1, wherein the plurality of memory chips comprises a plurality of dual in-line memories (DIMMs).

9. The apparatus of claim 1, wherein the apparatus is configured as a personal computer, a laptop computer, a tablet computer, a smartphone, or a wearable device.

10. A heatsink, comprising:
a first side;
a second side, opposite the first side;
a plurality of heatsink fins, extending from the first side, and configured to radiate heat;
a first fastening portion comprising a first hole; and
a second fastening portion comprising a second hole;
wherein the first fastening portion and the second fastening portion are configured to cause the heatsink to exert a force against a memory module; and
wherein the second side comprises a recess between the first fastening portion and the second fastening portion, and wherein the recess is configured to accommodate one or more memory chips.

11. The heatsink of claim 10, wherein the heatsink is monolithic.

12. A heatsink, comprising:
a first side;
a second side, opposite the first side;
a plurality of heatsink fins, extending from the first side, for radiating heat;
a first fastening portion comprising a first hole; and
a second fastening portion comprising a second hole;
wherein the first fastening portion and the second fastening portion are for causing the heatsink to exert a force against a memory module; and
wherein the second side comprises a recess between the first fastening portion and the second fastening portion, and wherein the recess is for accommodating one or more memory chips.

13. The heatsink of claim 12, wherein the heatsink is monolithic.

14. A method of assembling a memory module, comprising:
attaching a memory module comprising a plurality of memory chips to an interposer; and
attaching a heatsink to the interposer, wherein the attaching the heatsink to the interposer causes the interposer to exert a force against the memory module.

15. The method of claim 14, wherein the attaching the heatsink to the interposer comprises attaching the heatsink to the interposer with a common fastener.

16. The method of claim 14, wherein the attaching the heatsink to the interposer comprises attaching the heatsink to the interposer via the first hole and the second hole.

17. The method of claim 14, wherein the heatsink comprises:
a first side;
a second side, opposite the first side;
a plurality of heatsink fins, extending from the first side, for radiating heat;
a first fastening portion comprising a first hole; and
a second fastening portion comprising a second hole;
wherein the first fastening portion and the second fastening portion are for causing the heatsink to exert a force against a memory module; and
wherein the second side comprises a recess between the first fastening portion and the second fastening portion, and wherein the recess is for accommodating one or more memory chips.

18. The method of claim 14, wherein the heatsink is monolithic.
